(19) United States
(12) Patent Application Publication
(10) Pub. No.: US 2015/0340539 A1
(43) Pub. Date: Nov. 26, 2015

(54) ULTRAVIOLET SENSOR AND ELECTRONIC DEVICE USING ULTRAVIOLET SENSOR

(71) Applicant: Semiconductor Energy Laboratory Co., Ltd., Atsugi-shi (JP)

(72) Inventor: Jun KOYAMA, Sagamihara, Kanagawa (JP)

(21) Appl. No.: 14/712,292

(22) Filed: May 14, 2015

(30) Foreign Application Priority Data
May 21, 2014 (JP) 2014-104819

(51) Int. Cl. H01L 31/113; H01L 31/0224; H01L 31/032

(52) U.S. Cl. CPC H01L 31/1136; H01L 31/032; H01L 31/022408

(57) ABSTRACT

An ultraviolet light sensor (UV sensor) with low costs is provided. As a UV sensor element, an oxide semiconductor transistor including a drain electrode with a comb-like shape is used, so that the length of a border between the drain electrode and a channel region is greater than the length of a border between a source electrode and the channel region. As a result, the off-state current of the oxide semiconductor transistor can be increased without a significant increase in the gate width, improving the sensitivity of the UV sensor. In addition, a reduced area in the element is achieved to reduce costs of the UV sensor.

### BACKGROUND OF THE INVENTION

1. Field of the Invention

One embodiment of the present invention relates to an ultraviolet light sensor (UV sensor) including an oxide semiconductor, and particularly relates to a UV sensor utilizing the low off-state current of an oxide semiconductor transistor. One embodiment of the present invention also relates to an electronic device using the UV sensor. Note that one embodiment of the present invention is not limited to such a technical field. The technical field of one embodiment of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a light-emitting device, a power storage device, a memory device, a method for driving any of them, and a method for manufacturing any of them.

2. Description of the Related Art

In recent years, smartphones have experienced exponential growth worldwide. Having a variety of functions such as a TV and a game, the smartphones are no longer just mobile phones, but are small computers having a communication function. Such smartphones include various kinds of sensors: a touch sensor, which is indispensable for input on a display screen, a photosensor for measuring light intensity, a sensor for fingerprint authentication, and the like. In future, sensor functions for health care would be built into smartphones; for example, a UV sensor has been needed.

A variety of UV sensors have been proposed; one is a UV sensor including silicon as disclosed in Patent Document 1. In Patent Document 1, a UV sensor is constituted by a photodiode including silicon with a band gap of approximately 1.1 eV. The photodiode including silicon, however, has the disadvantage of a significant increase in dark current with increasing temperature and therefore cannot be used in a wide temperature range.

Furthermore, in the photodiode including silicon, current flows in response to light even in a visible light region. Hence, a filter is necessary for selectively irradiating the photodiode with UV light, leading to an increase in the costs of UV sensors.

As another UV sensor, the one including an oxide semiconductor is proposed. The oxide semiconductor, e.g., an In—Ga—Zn oxide, has a wide band gap of approximately 3.2 eV. It is known that a transistor including an oxide semiconductor (hereinafter also referred to as an oxide semiconductor transistor) has an extremely low off-state current. Note that the off-state current refers to a current that flows between a drain and a source when the transistor is off. The current flowing between the drain and the source is also referred to as a drain current.

It is also known that the off-state current increases with UV exposure. This enables the intensity of UV light to be estimated by sensing the off-state current in UV exposure. FIG. 11 is a schematic view showing the gate voltage (Vg)-drain current (Id) characteristics of an oxide semiconductor transistor; a curve 1101 represents the characteristics of the transistor without UV exposure, and a curve 1102 represents the characteristics of the transistor with UV exposure. As shown in FIG. 11, the off-state current of the oxide semiconductor transistor increases with UV exposure. FIG. 12 shows changes in the off-state current of oxide semiconductor transistors with respect to the wavelength of emitted light.

The measurement is performed at room temperature under a dry atmosphere in a state where a transistor is irradiated with light using a 300 W xenon light source (MAX-302 manufactured by Asahi Spectra Co., Ltd.) and the wavelength of the light is controlled with a band-pass filter. While the irradiance per unit wavelength is measured with a spectroradiometer (USR-45 manufactured by USHIO INC.), light is emitted to the transistor at a constant irradiance.

FIG. 12 shows that the off-state current hardly increases in the visible light region and increases in the UV region. Thus, a UV sensor can be achieved without any specific filter, reducing costs for the filter.

An example of using an oxide semiconductor for a UV sensor is disclosed in the following Patent Document 2.

### REFERENCES

### [Patent Documents]

### [Patent Document 1] Japanese Published Patent Application No. 2007-067331

### [Patent Document 2] Japanese Published Patent Application No. 2011-139045

### SUMMARY OF THE INVENTION

As mentioned above, the off-state current of an oxide semiconductor transistor varies with UV exposure, and a UV sensor can be obtained when the off-state current value is measured. However, the off-state current has an extremely small value; hence, an oxide semiconductor transistor needs to have a large gate width W to detect UV light. This causes an increase in the chip area of the UV sensor and consequently increases production costs. FIG. 2 is a plan view of a conventional oxide semiconductor transistor 200. As illustrated in FIG. 2, in the conventional oxide semiconductor transistor 200, a drain electrode 203 and a source electrode 204 are arranged symmetrically with respect to a gate electrode 202 and an active layer 201.

FIG. 13 shows the relationship between UV light intensity and off-state current. An oxide semiconductor transistor with L/W=3 μm/10000 μm is used, where L is a gate length and W is a gate width, and UV light with a wavelength of 350 nm is emitted. In FIG. 13, when the UV light intensity is 1 mW/cm², the off-state current at a source-drain voltage Vds of 10 V is approximately 1 pA. When the effect of noise or the like is considered, a sensor circuit preferably has a higher sensor current (an off-state current obtained by UV exposure).

For example, in the case where the sensor current needs to be approximately 100 times as high as the value shown in FIG. 13, since the oxide semiconductor transistor in FIG. 13 has a gate width W of 10000 μm, the gate width W increases to 1000000 μm when the sensor current is increased 100-fold by only increasing the gate width W. As a result, the area of the transistor considerably increases.

In view of the above technical background, an object of one embodiment of the present invention is to provide a UV sensor that can be used in a wide temperature range. Another object of one embodiment of the present invention is to provide a UV sensor that does not use a filter and therefore has reduced costs. Still another object of one embodiment of the present invention is to provide a UV sensor that has increased sensitivity to UV light, reduced transistor size, and reduced chip area.

In addition, an object of one embodiment of the present invention is to provide an electronic device including a UV sensor that can be used in a wide temperature range. Another object of one embodiment of the present invention is to provide an electronic device including a UV sensor that does not use a filter and therefore has reduced costs. Another object of one embodiment of the present invention is to provide an electronic device including a UV sensor that has increased sensitivity to UV light, reduced transistor size, and reduced chip area.

Still another object of one embodiment of the present invention is to provide a novel semiconductor device or the like. Note that the description of these objects does not disturb the existence of other objects. One embodiment of the present invention does not necessarily achieve all the objects. Other objects will be apparent from and can be derived from the description of the specification, the drawings, the claims, and the like.

One embodiment of the present invention is a UV sensor in which the intensity of UV light is measured with the value of a current generated when an oxide semiconductor element is irradiated with UV light. The oxide semiconductor element has a transistor structure, and a drain electrode of the oxide semiconductor element has a comb-like shape.

One embodiment of the present invention is a UV sensor in which the intensity of UV light is measured with the value of a current generated when an oxide semiconductor element is irradiated with UV light. The oxide semiconductor element has a transistor structure, and the length of a border between a drain electrode and a channel region of the oxide semiconductor element is longer than the length of a border between a source electrode and the channel region of the oxide semiconductor element.

In the above, the transistor is a bottom-gate transistor.

In the above, the oxide semiconductor contains In, Ga, and Zn.

One embodiment of the present invention is an electronic device including the aforementioned UV sensor.

According to one embodiment of the present invention, a UV sensor that can be used in a wide temperature range can be provided. According to another embodiment of the present invention, a UV sensor that does not use a filter and therefore has reduced costs can be provided. According to still another embodiment of the present invention, a UV sensor that has increased sensitivity to UV light, reduced transistor size, and reduced chip area can be provided.

Furthermore, according to one embodiment of the present invention, an electronic device including a UV sensor that can be used in a wide temperature range can be provided. According to another embodiment of the present invention, an electronic device including a UV sensor that does not use a filter and therefore has reduced costs can be provided. According to still another embodiment of the present invention, an electronic device including a UV sensor that has increased sensitivity to UV light, reduced transistor size, and reduced chip area can be provided. In addition, a novel semiconductor device or the like can be provided. Note that the description of these effects does not disturb the existence of other effects. One embodiment of the present invention does not necessarily achieve all the above effects. Other effects will be apparent from and can be derived from the description of the specification, the drawings, the claims, and the like.

### BRIEF DESCRIPTION OF THE DRAWINGS

In the accompanying drawings:

FIG. 1 is a plan view of an oxide semiconductor transistor;

FIG. 2 is a plan view of an oxide semiconductor transistor;

FIG. 3 is a plan view of an oxide semiconductor transistor;

FIGS. 4A and 4B are a plan view and a cross-sectional view of an oxide semiconductor transistor;

FIG. 5 is a plan view of an oxide semiconductor transistor;

FIG. 6 illustrates a UV light detection circuit including a sensor element;

FIG. 7 is a timing chart of the UV light detection circuit;

FIG. 8 is a diagram in which a UV sensor is combined with a microcontroller;

FIG. 9 is a block diagram of a portable communication device;

FIG. 10 is a cross-sectional view of a UV sensor;

FIG. 11 shows the characteristics of an oxide semiconductor;

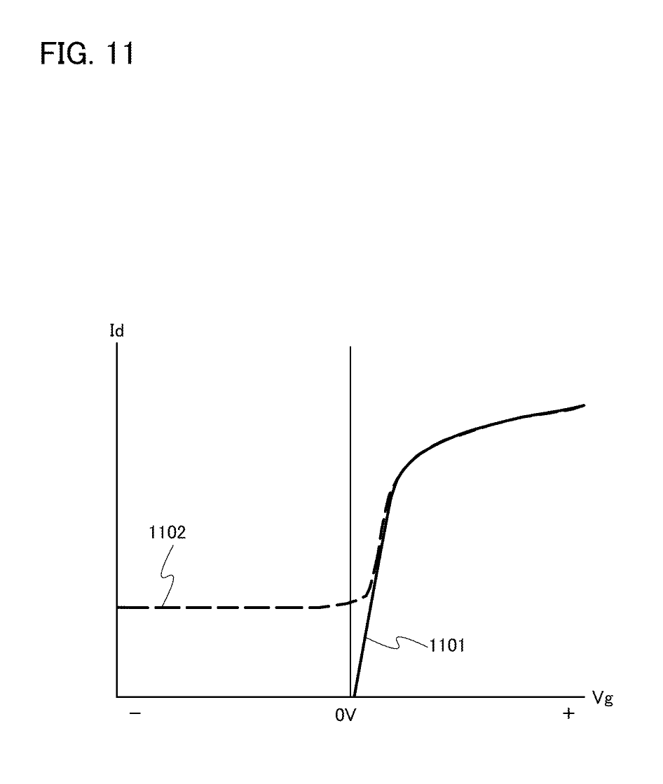

FIG. 12 shows the current characteristics of a conventional sensor;

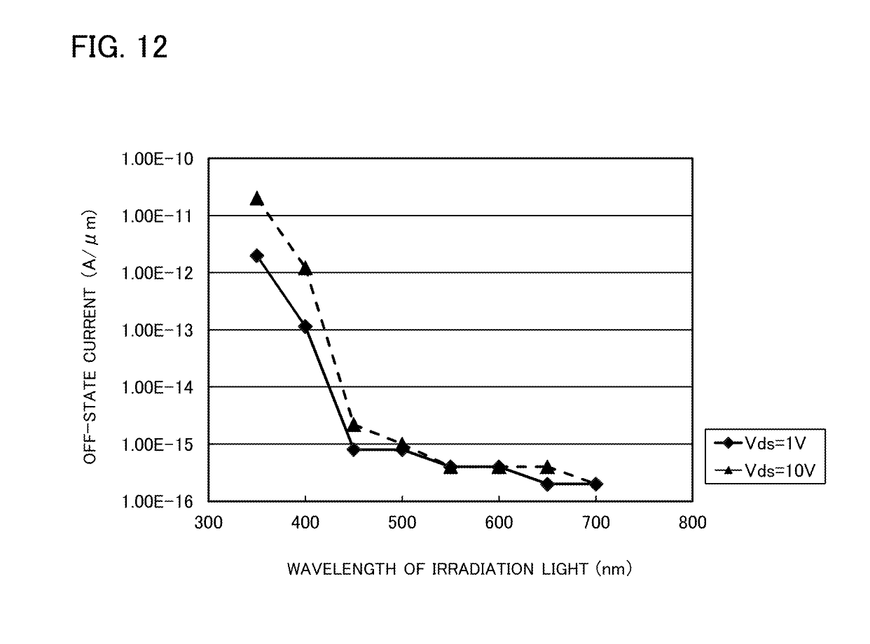

FIG. 13 shows the current characteristics of a conventional sensor;

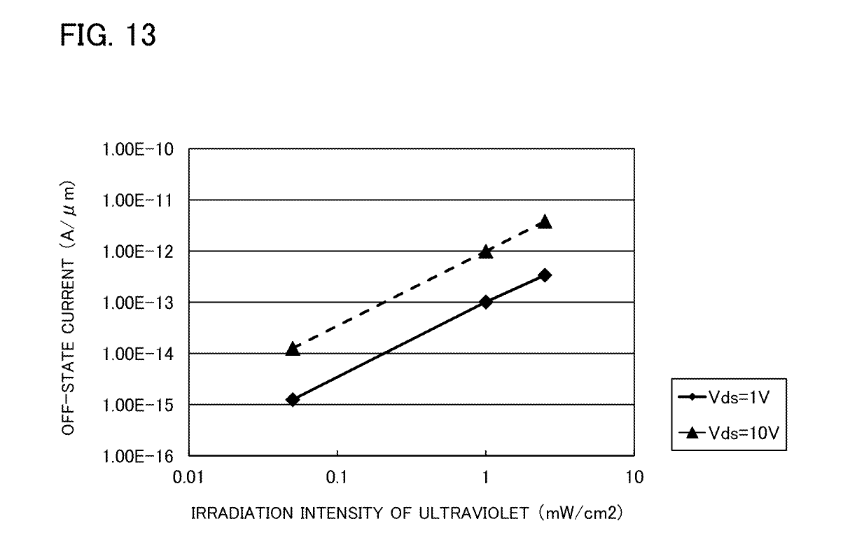

FIGS. 14A and 14B illustrate structure examples of sensor element packages; and

FIGS. 15A to 15C illustrate structure examples of application products.

### DETAILED DESCRIPTION OF THE INVENTION

Embodiments of the present invention will be described in detail below with reference to drawings. Note that the present invention is not limited to the following description, and it will be easily understood by those skilled in the art that various changes and modifications can be made without departing from the spirit and scope of the present invention. Therefore, the present invention should not be construed as being limited to description of the embodiments.

Note that a sensor circuit of one embodiment of the present invention can be used in a wide variety of semiconductor devices such as integrated circuits, RF tags, and semiconductor display devices. Semiconductor devices including a sensor circuit are included in the category of one embodiment of the present invention. Integrated circuits include, in their category, large scale integrated circuits (LSIs) including a microprocessor, an image processing circuit, a digital signal processor (DSP), and a microcontroller, and programmable logic devices (PLDs) such as a field programmable gate array (FPGA) and a complex PLD (CPLD). Semiconductor display devices include, in their category, liquid crystal display devices, light-emitting devices having pixels each provided with a light-emitting element typified by an organic light-emitting diode, electronic paper, digital micromirror devices (DMDs), plasma display panels (PDPs), and field emission displays (FEDs).

Functions of a source and a drain might be switched depending on operation conditions, for example, when a transistor having opposite conductivity is employed or the direction of current flow is changed in circuit operation. Thus, the terms “source” and “drain” can be switched in this specification.

### Embodiment 1

### Technique of One Embodiment of the Present Invention

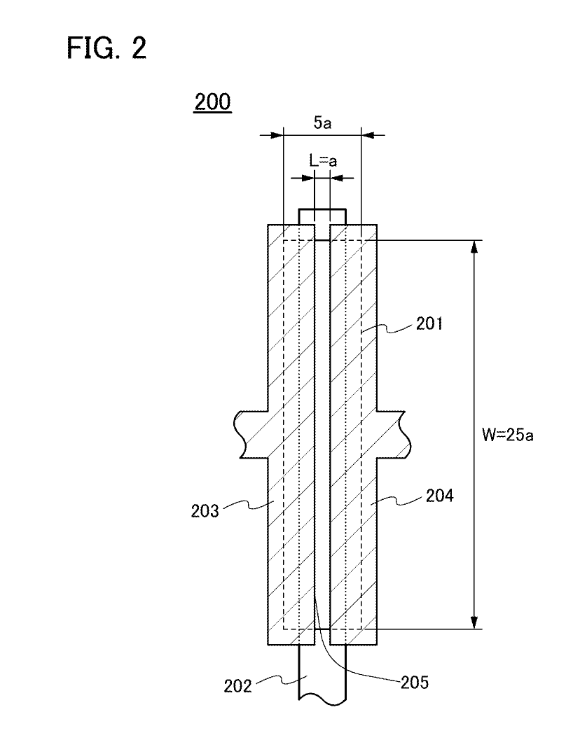

The following description will be made while being compared to the conventional oxide semiconductor transistor 200 illustrated in the plan view of FIG. 2. The oxide semiconductor transistor 200 illustrated in FIG. 2 includes the gate electrode 202, the active layer 201, the drain electrode 203, and the source electrode 204. Given the minimum feature size is a (μm) in FIG. 2, the channel length L is a (μm), the channel width W is 25a (μm), and the size of the active layer 201 is 5a (μm)×25a (μm). The oxide semiconductor transistor 200 has a bottom-gate structure. The UV light intensity is obtained by irradiating a channel region of the active layer 201 with UV light and measuring a current flowing between a drain and a source. In FIG. 2, the length of a border 205 between the drain electrode 203 and the channel region is the same as the channel width, 25a (μm). Note that in this specification and the like, a length of a border between a drain electrode and a channel region refers to a total length of sides of the drain electrode which overlap with an active layer. In addition, a length of a border between a source electrode and a channel region refers to a total length of sides of the source electrode which overlap with an active layer.

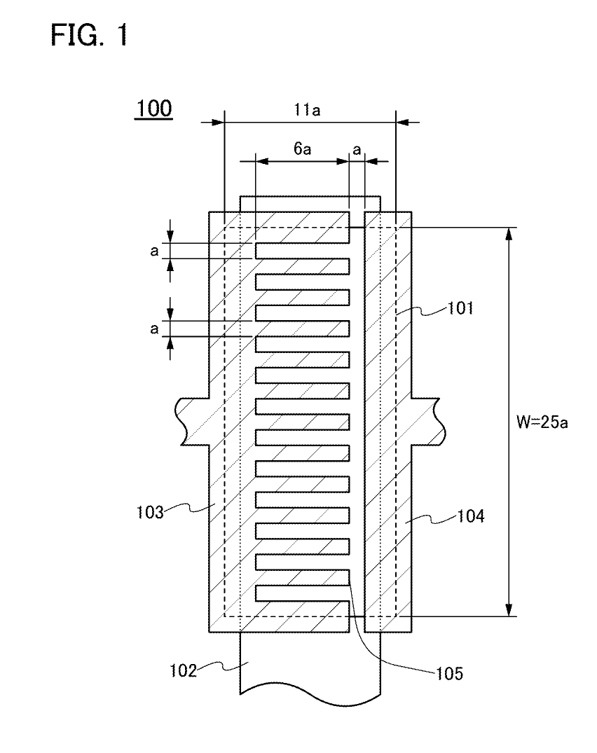

FIG. 1 illustrates an oxide semiconductor transistor 100 of one embodiment of the present invention, which includes a gate electrode 102, an active layer 101, a drain electrode 103, and a source electrode 104. In the oxide semiconductor transistor 100, the drain electrode 103 has a comb-like shape, so that the length of a border 105 between the drain electrode 103 and a channel region of the active layer 101 is greater than the length of a border between the source electrode 104 and the channel region. FIG. 1 shows a comb-like drain electrode as an example; however, the shape of the drain electrode is not limited thereto. The shape of the border between the drain electrode and the channel region may have any of various shapes such as a wave shape, a saw-like shape, or a triangular wave shape. The off-state current of a transistor (a current flowing between a drain and a source when the transistor is off) depends on the length of the border between a channel region and the drain. This is because the off-state current is determined not by the resistance of the channel region but by the state of the border between the drain electrode 103 and the channel region. The oxide semiconductor transistor 100 illustrated in FIG. 1, like the oxide semiconductor transistor 200 illustrated in FIG. 2, has a bottom-gate structure in which the minimum feature size is a (μm) and the channel width W is 25a (μm). Note that the size of the active layer 101 is 11a (μm)×25a (μm).

In the oxide semiconductor transistor 100 illustrated in FIG. 1, the drain electrode has a comb-like shape; a tooth (a projection) of the comb has a length of 6a (μm), a width of a (μm), and a distance between teeth of a (μm). When the number of steps of the comb is 12 (the number of teeth is 11), the length of the border 105 between the drain electrode 103 and the channel region can be 169a (μm), which is 6.76 times as long as that in the conventional oxide semiconductor transistor illustrated in FIG. 2. In this manner, the off-state current can be increased several-fold when the drain electrode 103 has a comb-like shape. Even in the case where the length of the tooth of the comb is the minimum feature size, a (μm), the length of the border between the drain electrode and the channel region can be 1.96 times as long as that of the border with the shape illustrated in FIG. 2.

As for the area of the active layer, the conventional transistor illustrated in FIG. 2 includes the active layer with an area of 5a (μm)×25a (μm)=125a² (μm²), whereas the oxide semiconductor transistor of one embodiment of the present invention illustrated in FIG. 1 includes the active layer with an area of 11a (μm)×25a (μm)=275a² (μm²), which increases 2.2-fold. In the conventional shape, the area of the active layer needs to be increased 6.76-fold in order to achieve a 6.76-fold increase in off-state current. By using the shape shown in this embodiment, the area of the active layer only needs to be increased approximately 2-fold. The use of one embodiment of the present invention thus allows reducing of the chip size of a UV sensor element and reducing of costs of a UV sensor. Furthermore, it is possible to provide a UV sensor that requires no additional filter and has a low leakage current even in a high temperature environment.

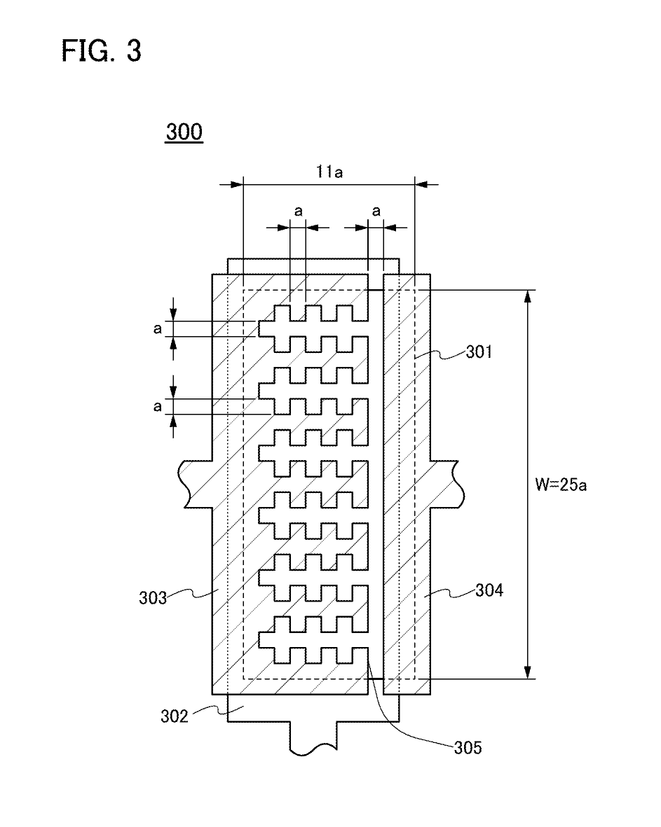

As in an oxide semiconductor transistor 300 illustrated in FIG. 3, a drain electrode 303 may include fine projections and depressions so as to increase the length of a border 305 between a channel region and the drain electrode 303. The oxide semiconductor transistor 300 includes a gate electrode 302, an active layer 301, the drain electrode 303, and a source electrode 304. The shape as illustrated in FIG. 3 is effective when miniaturization further proceeds.

For example, in one embodiment of the present invention, a transistor can be formed using any of a variety of substrates. The type of a substrate is not limited to a certain type. Examples of the substrate include a semiconductor substrate (e.g., a single crystal substrate or a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, paper including a fibrous material, and a base material film. Examples of the glass substrate include a barium borosilicate glass substrate, an aluminoborosilicate glass substrate, and a soda lime glass substrate. Examples of the flexible substrate, the attachment film, the base film, and the like are substrates of plastics typified by polyethylene terephthalate (PET), polyethylene naphthalate (PEN), and polyether sulfone (PES). Other examples are substrates of synthetic resins such as acrylic. Other examples are polypropylene, polyester, polyvinyl fluoride, polyvinyl chloride, and the like. Other examples are polyamide, polyimide, aramid, epoxy, an inorganic vapor deposition film, paper, and the like. Specifically, the use of semiconductor substrates, single crystal substrates, SOI substrates, or the like enables the manufacture of small-sized transistors with a small variation in characteristics, size, shape, or the like and with high current capability. A circuit using such transistors achieves lower power consumption or higher integration.

Alternatively, a flexible substrate may be used as the substrate and the transistor may be provided directly on the flexible substrate. Still alternatively, a separation layer may be provided between the substrate and the transistor. The separation layer can be used when part or the whole of a semiconductor device formed over the separation layer is separated from the substrate and transferred onto another substrate. In such a case, the transistor can be transferred to a substrate having low heat resistance or a flexible substrate as well. For the above separation layer, for example, a stack including inorganic films, which are a tungsten film and a silicon oxide film, or an organic resin film of polyimide or the like formed over a substrate can be used.

In other words, after the transistor is formed using a substrate, the transistor may be transferred to another substrate. Examples of a substrate to which a transistor is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupra, rayon, or regenerated polyester), or the like), a leather substrate, and a rubber substrate. When such a substrate is used, a transistor with excellent properties or a transistor with low power consumption can be formed, a device with high durability or high heat resistance can be provided, or a reduction in weight or thickness can be achieved.

For example, in this specification and the like, when it is explicitly described that X and Y are connected, the case where X and Y are electrically connected, the case where X and Y are functionally connected, and the case where X and Y are directly connected are included therein. Accordingly, a connection relation other than connection relations shown in drawings and texts is also included, without being limited to a predetermined connection relation, for example, a connection relation shown in the drawings and the texts.

Here, each of X and Y denotes an object (e.g., a device, an element, a circuit, a wiring, an electrode, a terminal, a conductive film, a layer, or the like).

In the case where X and Y are electrically connected, for example, one or more elements (e.g., a switch, a transistor, a capacitor, an inductor, a resistor, a diode, a display element, a light-emitting element, and a load) that enable an electrical connection between X and Y can be connected between X and Y. Note that the switch is controlled to be turned on or off. That is, the switch has a function of determining whether current flows or not by being turned on or off (becoming an on state or an off state). Alternatively, the switch has a function of selecting and changing a current path.

In the case where X and Y are functionally connected, for example, one or more circuits (e.g., a logic circuit such as an inverter, a NAND circuit, or a NOR circuit; a signal converter circuit such as a DA converter circuit, an AD converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a storage circuit; and a control circuit) that enable a functional connection between X and Y can be connected between X and Y. Note that for example, in the case where a signal output from X is transmitted to Y even when another circuit is interposed between X and Y, X and Y are functionally connected.

Note that when it is explicitly described that X and Y are connected, the case where X and Y are electrically connected (i.e., the case where X and Y are connected with another element or another circuit provided therebetween), the case where X and Y are functionally connected (i.e., the case where X and Y are functionally connected with another circuit provided therebetween), and the case where X and Y are directly connected (i.e., the case where X and Y are connected without another element or another circuit provided therebetween) are included therein. That is, when it is explicitly described that “X and Y are electrically connected”, the description is the same as the case where it is explicitly only described that “X and Y are connected”.

Note that, for example, the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y, can be expressed by using any of the following expressions.

The expressions include, for example, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”, “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order”, and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order”. When the connection order in a circuit configuration is defined by an expression similar to the above examples, a source (or a first terminal or the like) and a drain (or a second terminal or the like) of a transistor can be distinguished from each other to specify the technical scope. Note that these expressions are examples and there is no limitation on the expressions. Here, each of X, Y, Z1, and Z2 denotes an object (e.g., a device, an element, a circuit, a wiring, an electrode, a terminal, a conductive film, or a layer). Even when independent components are electrically connected to each other in a circuit diagram, one component has functions of a plurality of components in some cases. For example, when part of a wiring also functions as an electrode, one conductive film functions as the wiring and the electrode. Thus, “electrical connection” in this specification includes in its category such a case where one conductive film has functions of a plurality of components.

In this embodiment, one embodiment of the present invention is described. Other embodiments of the present invention will be described in the other embodiments. Note that one embodiment of the present invention is not limited thereto. An example in which one embodiment of the present invention is applied to a UV sensor is described; however, one embodiment of the present invention is not limited thereto. Depending on circumstances, one embodiment of the present invention is not necessarily applied to a UV sensor. One embodiment of the present invention may be applied to, for example, another sensor. One embodiment of the present invention may also be applied to, for example, a transistor that controls the amount of current.

This embodiment can be implemented in appropriate combination with any of the other embodiments.

### Embodiment 2

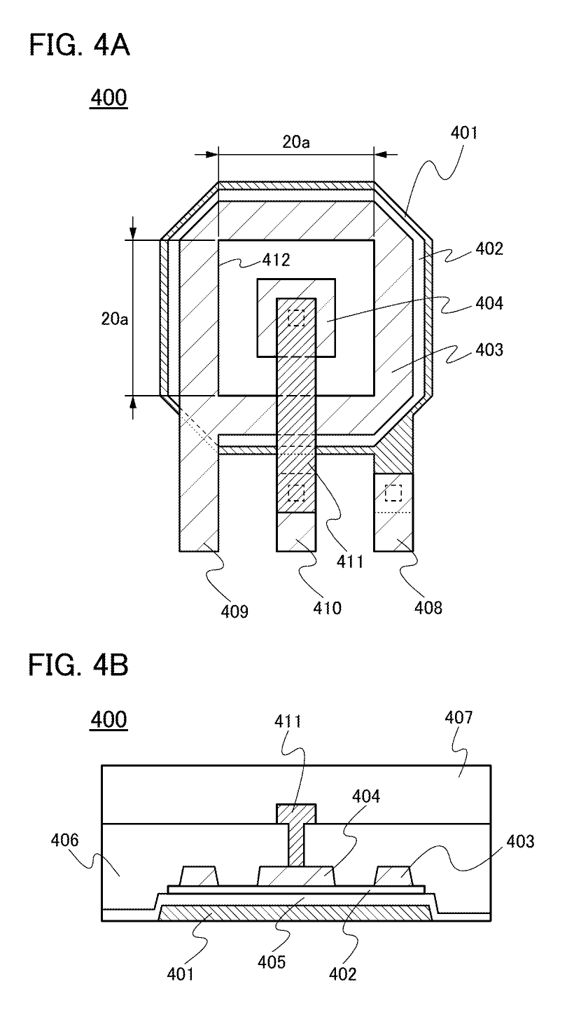

FIG. 4A is a plan view of a transistor having a shape different from the shapes of the oxide semiconductor transistors illustrated in FIG. 1 to FIG. 3. A transistor 400 illustrated in FIG. 4A includes a gate electrode 401, an active layer 402, a drain electrode 403, a source electrode 404, an upper wiring 411, a drain leading electrode 409, a source leading electrode 410, and a gate leading electrode 408. FIG. 4B is a cross-sectional view of the transistor 400. The transistor 400 includes, in addition to the above, a gate insulating film 405, a first interlayer film 406, and a second interlayer film 407. The gate electrode 401 is connected to the leading electrode 408, the drain electrode 403 is connected to the leading electrode 409, and the source electrode 404 is connected to the leading electrode 410 through the upper wiring 411 formed over the first interlayer film 406. Since the drain electrode 403 and the source electrode 404 are formed in the same layer, the source electrode 404 needs to intersect the drain electrode 403 when led to the outside. Therefore, in FIGS. 4A and 4B, an opening is formed in a region of the first interlayer film 406 that overlaps with the source electrode 404, and the source electrode 404 is connected to the upper wiring 411 through the opening. In addition, an opening is formed in a region of the first interlayer film 406 that overlaps with the leading electrode 410, and the leading electrode 410 is connected to the upper wiring 411 through the opening. Such a shape of the transistor 400 is employed when, for example, the withstand voltage of the transistor needs to increase.

In the structure of FIGS. 4A and 4B, when the length of the periphery of the drain electrode 403 that is closer to the source electrode 404 is twice as long as that of the periphery of the source electrode 404, the length of the border between a channel region and the drain electrode is twice as long as that of the border between the channel region and the source electrode. By applying one embodiment of the present invention to this example, the length of the border between the channel region and the drain electrode can be increased more than two-fold.

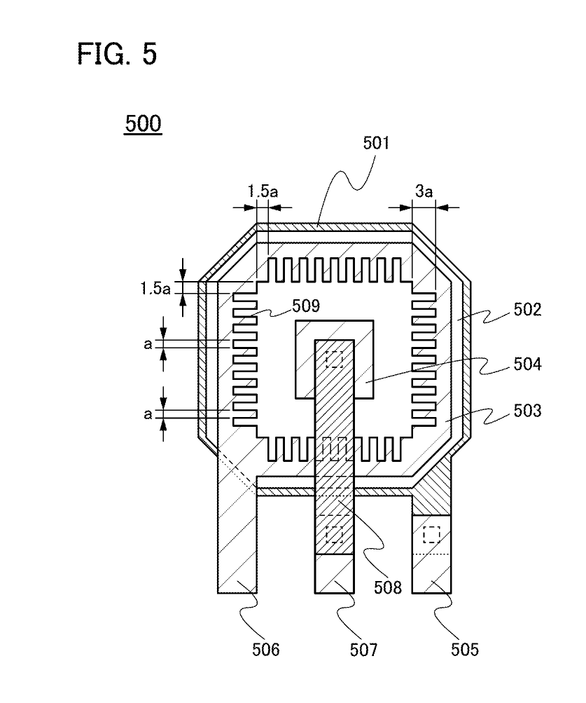

A transistor 500 illustrated in FIG. 5 is an oxide semiconductor transistor of one embodiment of the present invention, which has a structure in which a source electrode is surrounded by a drain electrode. The transistor 500 illustrated in the plan view of FIG. 5 includes a gate electrode 501, an active layer 502, a drain electrode 503, a source electrode 504, a gate leading electrode 505, a drain leading electrode 506, a source leading electrode 507, and an upper wiring 508. In the transistor 500 illustrated in FIG. 5, the drain electrode 503 has a comb-like shape and surrounds the source electrode 504, so that a border 509 between a channel region and the drain electrode has a long length. FIG. 5 shows a comb-like drain electrode as an example; however, the shape of the drain electrode is not limited thereto. The shape of the border between the drain electrode and the channel region may have any of various shapes such as a wave shape, a saw-like shape, or a triangular wave shape.

Given the minimum feature size is a (μm) in FIG. 5, the length of the border 509 is 296a (μm). In the shape of FIG. 4A, the length of a border 412 between the drain electrode and the channel region is 80a (μm), which means that the use of one embodiment of the present invention increases the length of the border 3.7-fold. In this manner, a high off-state current can be obtained from a small area in a UV sensor including the oxide semiconductor transistor of one embodiment of the present invention, which results in a decrease in the chip area of the UV sensor. Note that the cross-sectional structure of the oxide semiconductor transistor illustrated in FIG. 5 is similar to that illustrated in FIG. 4B. The use of one embodiment of the present invention thus allows reducing of the chip size of a UV sensor element and reducing of costs of a UV sensor. Furthermore, it is possible to provide a UV sensor that requires no additional filter and has a low leakage current even in a high temperature environment.

This embodiment can be implemented in appropriate combination with any of the other embodiments.

### Embodiment 3

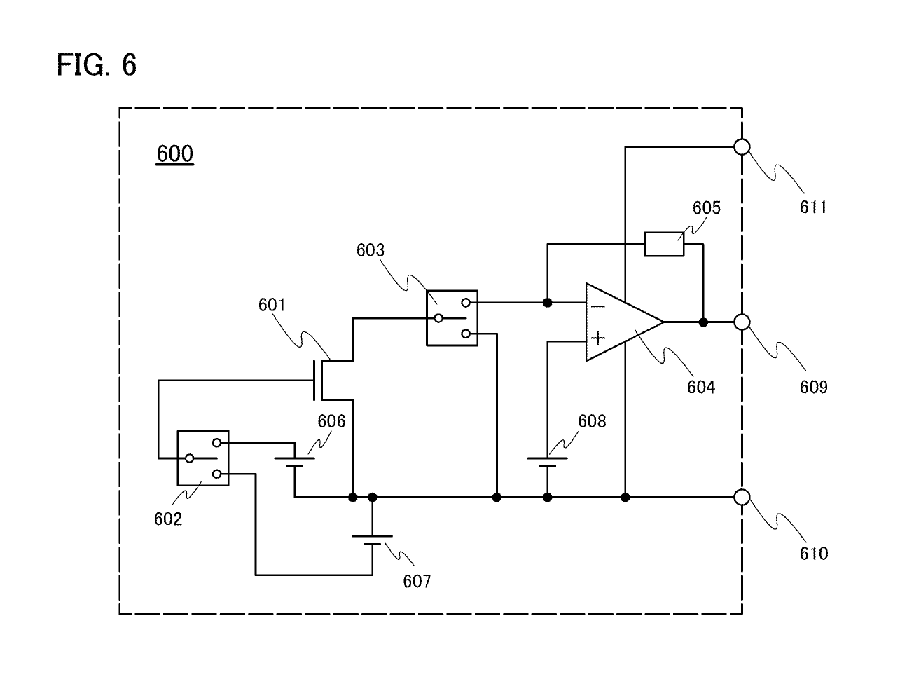

FIG. 6 illustrates an example of an ultraviolet light detection circuit (UV light detection circuit) including the UV sensor of one embodiment of the present invention. Note that the structure of the detection circuit including the UV sensor of one embodiment of the present invention is not limited to that of FIG. 6. A UV light detection circuit 600 illustrated in FIG. 6 includes an oxide semiconductor transistor 601, a switch 602, a switch 603, a differential amplifier 604, a resistor 605, a power source 606, a power source 607, a power source 608, a terminal 609, a terminal 611, and a terminal 610. The switches 602 and 603 each include first to third terminals. A high power source potential (also referred to as Vdd) is supplied to the terminal 611, and a low power source potential (also referred to as Vss) is supplied to the terminal 610. Note that the power source potential Vdd is higher than the power source potential Vss, and Vss is lower than Vdd. A ground potential may be used as Vdd or Vss. For example, in the case where Vdd is the ground potential, Vss is lower than the ground potential, and in the case where Vss is the ground potential, Vdd is higher than the ground potential.

A gate of the oxide semiconductor transistor 601 is connected to a first terminal of the switch 602, a source thereof is connected to the terminal 610, and a drain thereof is connected to a first terminal of the switch 603. A second terminal of the switch 602 is connected to the power source 606, and a third terminal thereof is connected to the power source 607. Whether the first terminal of the switch 602 is connected to its second terminal or third terminal can be selected. A second terminal of the switch 603 is connected to one terminal of the resistor 605 and an inverting input terminal of the differential amplifier 604. A third terminal of the switch 603 is connected to the terminal 610. Whether the first terminal of the switch 603 is connected to its second terminal or third terminal can be selected. An output of the differential amplifier 604 and the other electrode of the resistor 605 are connected to the terminal 609. A power source is supplied to the differential amplifier 604 through the terminal 611 and the terminal 610. A non-inverting input terminal of the differential amplifier 604 is connected to the power source 608.

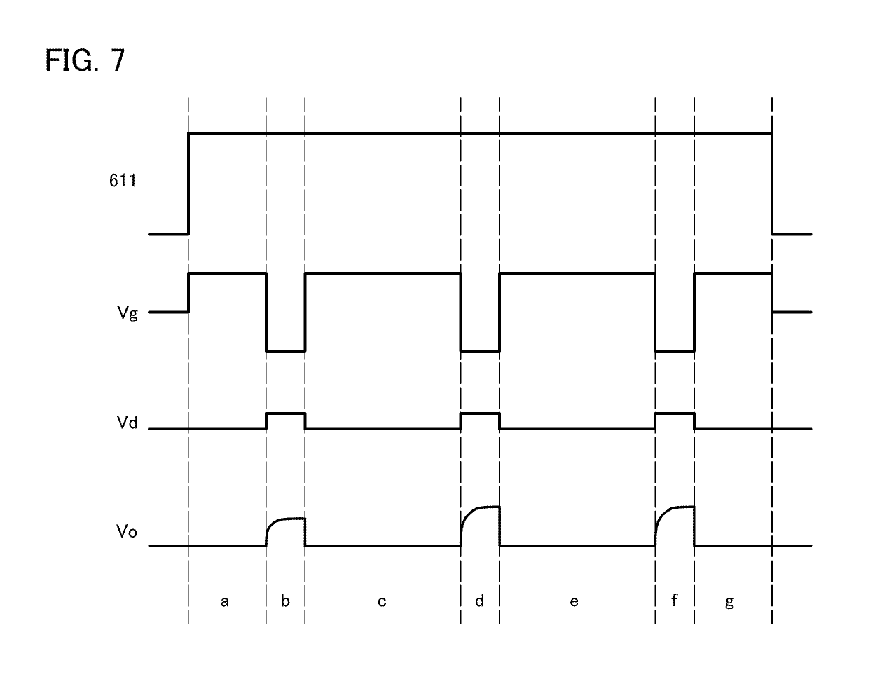

Next, operation of the UV light detection circuit 600 will be described with reference to a timing chart shown in FIG. 7. In the following description, Vss supplied to the terminal 610 is regarded as GND (ground potential). In a first period (a), the first terminal of the switch 602 is connected to the second terminal thereof. In addition, the first terminal of the switch 603 is connected to the third terminal thereof. Furthermore, Vdd is supplied to the terminal 611 and the power sources 606, 607, and 608 are turned on. In the period (a), which is in a non-measurement mode, the gate of the oxide semiconductor transistor 601 is connected to the power source 606 through the switch 602 and the drain thereof is connected to the terminal 610 through the switch 603. In the case where the oxide semiconductor transistor 601 is an n-type transistor, a gate voltage (a potential difference between a gate and a source with the source potential used as a reference, also referred to as Vg) exceeds the threshold voltage, so that the oxide semiconductor transistor 601 is turned on. Furthermore, the drain of the oxide semiconductor transistor 601 is electrically connected to the terminal 610 and disconnected from the differential amplifier 604 through the switch 603. Accordingly, an output voltage (also referred to as Vo) of the differential amplifier 604 is not affected by the oxide semiconductor transistor 601. Note that in the period (a), the source and the drain of the oxide semiconductor transistor 601 have the same potential; hence, a drain voltage (a potential difference between a drain and a source with the source potential used as a reference, also referred to as Vd) is 0 V.

In a subsequent period (b), the states of the switches 602 and 603 are changed so that the gate of the oxide semiconductor transistor 601 is connected to the power source 607 through the switch 602. Here, the power source 607 is set to have a potential lower than that supplied to the terminal 610. As a result, the gate potential of the oxide semiconductor transistor 601 is lower than the source potential. In other words, Vg is lower than the threshold voltage, whereby the oxide semiconductor transistor 601 is turned off. The drain of the oxide semiconductor transistor 601 is connected to the inverting input terminal of the differential amplifier 604 through the switch 603. When UV light is emitted in this state, a current flows from the drain to the source of the oxide semiconductor transistor 601. Since the drain of the oxide semiconductor transistor 601 is connected to the non-inverting input terminal of the differential amplifier 604 and the resistor 605, a current equivalent to the drain current of the oxide semiconductor transistor 601 flows through the resistor 605, thereby generating a potential difference between the terminals of the resistor 605. The differential amplifier 604 outputs a voltage corresponding to the potential difference between the terminals of the resistor 605; accordingly, the amount of UV exposure can be obtained by measuring the voltage of the terminal 609.

In a period (c) after the measurement, the states of the switches 602 and 603 are changed again, so that the gate of the oxide semiconductor transistor 601 is connected to the power source 606 and the drain thereof is connected to the terminal 610. In a period (d), measurement is performed in a manner similar to that in the period (b). By repeating these steps, a positive and negative voltage is alternately applied to the gate of the oxide semiconductor transistor 601, which prevents deterioration of the oxide semiconductor transistor 601. Note that the changing of states with the switches 602 and 603 is not necessarily performed in the case where the oxide semiconductor transistor 601 is a transistor that is less likely to deteriorate even with long-term application of the same voltage. After the measurement in a period (f), the states of the switches 602 and 603 are changed in a period (g) so that the gate of the oxide semiconductor transistor 601 is connected to the power source 606 and the drain thereof is connected to the terminal 610. Then, the terminal 611 and the power sources 606, 607, and 608 are turned off to complete the measurement.

This embodiment can be implemented in appropriate combination with any of the other embodiments.

### Embodiment 4

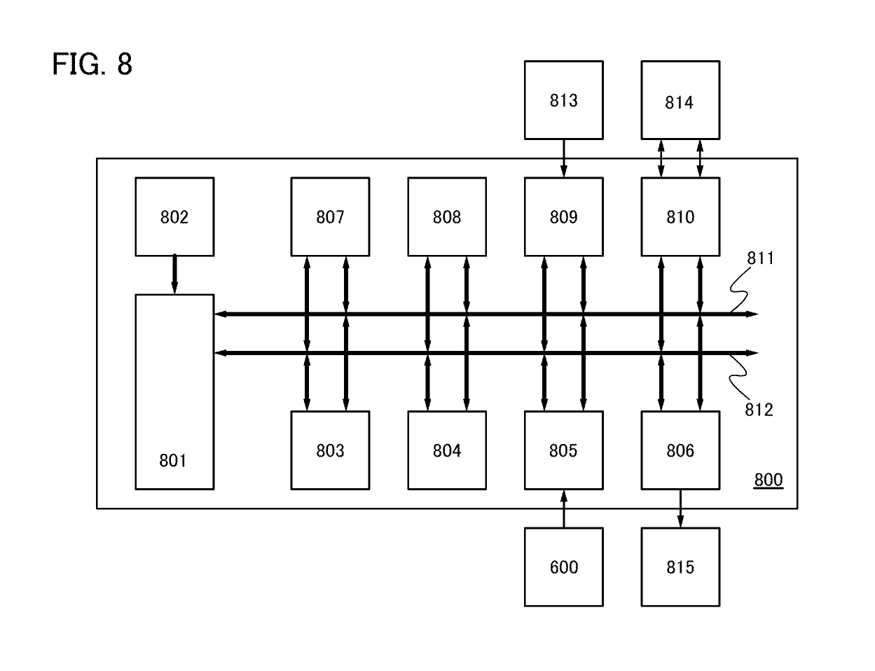

A module that is constituted by the UV light detection circuit 600 of one embodiment of the present invention and a microcontroller 800 can be easily used for a variety of electronic devices. FIG. 8 shows the connection between the microcontroller 800 and the UV light detection circuit 600 of one embodiment of the present invention illustrated in FIG. 6. The microcontroller 800 includes a CPU core 801, a clock generation circuit 802, a watchdog 803, a timer 804, an analog to digital (AD) converter 805, a display control circuit 806, a flash memory or ROM 807, a RAM 808, a power source control circuit 809, an input/output (I/O) interface 810, an address bus 811, and a data bus 812.

The CPU core 801 conducts a variety kinds of processing and transmits data to each circuit via the address bus 811 and the data bus 812. The clock generation circuit 802 generates a clock to be supplied to each circuit in the microcontroller 800. The watchdog 803 detects malfunction in the microcontroller and produces an alarm when finding malfunction. When the microcontroller 800 is intermittently driven, the timer 804 measures the time. The AD converter 805 converts an input analog signal into a digital signal. The display control circuit 806 controls a display circuit 815 such as a liquid crystal display device (LCD) module. A program is stored in the flash memory or ROM 807 and data is stored in the RAM 808. The power source control circuit 809 is connected to an external power source 813 to control the power supply to each circuit. The I/O interface 810 communicates data with an external bus 814. Note that the configuration of the microcontroller 800 is not limited to the above.

The UV light detection circuit 600 detects UV light and outputs an analog signal based on the intensity of the UV light. The analog signal is converted into a digital signal in the AD converter 805. The converted signal of the UV light intensity is subjected to arithmetic processing in the CPU core 801 and then stored in the RAM 808, and as needed, output to the external bus 814 via the I/O interface 810. The signal of the UV light intensity may be generated in the CPU core 801 by using the value of a signal that has been converted into a digital signal in the AD converter 805 and the data that is stored in the ROM 807 or the RAM 808 in advance.

Note that the CPU core 801 may have processing functions such as a filter function and a linearized function. The filter function removes noise from a signal. The linearized function performs correction so that the output of the UV light detection circuit 600 and the intensity of UV light have a linear relationship.

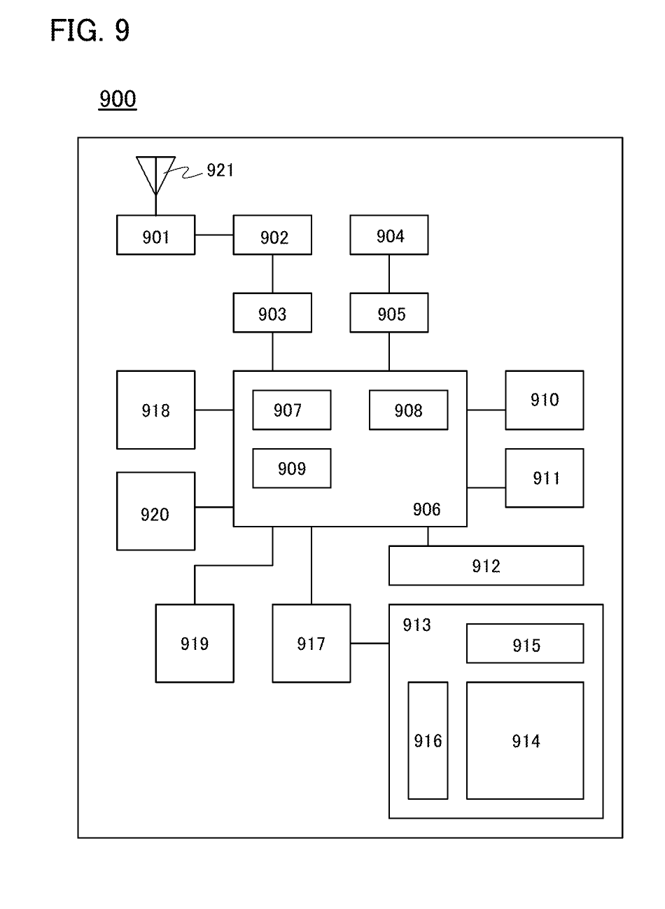

FIG. 9 is a block diagram of a portable communication device 900 typified by a cellular phone, a smartphone, and a tablet in which the UV light detection circuit of one embodiment of the present invention is employed. As illustrated in FIG. 9, the portable communication device 900 includes an antenna 921, a radio frequency (RF) circuit 901, an analog baseband circuit 902, a digital baseband circuit 903, a battery 904, a power source circuit 905, an application processor 906, a flash memory 910, a DRAM 911, a touch sensor 912, a display device 913, a display controller 917, an audio circuit 918, a UV light detection circuit 919, a camera module 920, and the like. The display device 913 includes a display portion 914, a scan driver 916, and a data driver 915. Similarly to the aforementioned microcontroller, the application processor 906 in the portable communication device 900 includes a CPU core 907, a memory 908, an AD converter 909, and the like. An analog signal input from the UV light detection circuit 919 is converted into a digital signal in the AD converter 909 and subjected to arithmetic processing in the CPU core 907.

The UV light detection circuit 919 detects UV light, and display based on the intensity of the UV light can be performed on the display device 913 via the display controller 917. In addition, an alarm can be activated via the audio circuit 918 to warn a user.

This embodiment can be implemented in appropriate combination with any of the other embodiments.

### Embodiment 5

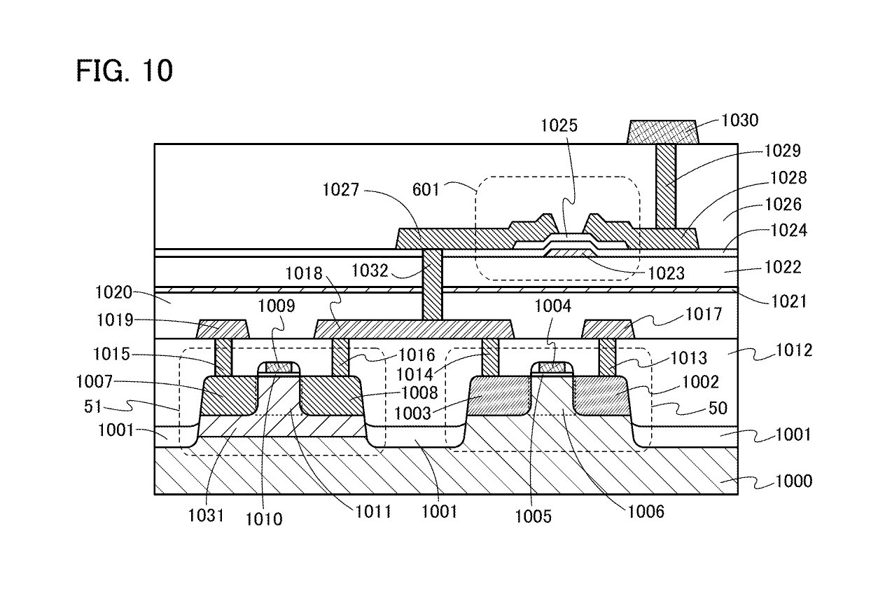

FIG. 10 illustrates an example of a cross-sectional structure of the UV light detection circuit of one embodiment of the present invention. FIG. 10 shows an example in which the oxide semiconductor transistor 601 including a channel formation region in an oxide semiconductor film is formed over an n-type transistor 50 and a p-type transistor 51 each of which includes a channel formation region in a single crystal silicon substrate.

Note that the n-type transistor 50 and the p-type transistor 51 correspond to examples of transistors included in the switch 602, the switch 603, the differential amplifier 604, and the like of the UV light detection circuit 600 illustrated in FIG. 6. The active layer in each of the n-type transistor 50 and the p-type transistor 51 can be an amorphous, microcrystalline, polycrystalline, or single crystal semiconductor film of silicon, germanium, or the like. Alternatively, the channel formation region of the n-type transistor 50 may be formed in an oxide semiconductor film.

When the n-type transistor 50 and the p-type transistor 51 are formed using a thin silicon film, any of the following can be used, for example: amorphous silicon formed by a sputtering method or a vapor phase growth method such as a plasma-enhanced CVD method; polycrystalline silicon obtained by crystallization of amorphous silicon by laser annealing or the like; and single crystal silicon obtained by separation of a surface portion of a single crystal silicon wafer by implantation of hydrogen ions or the like into the silicon wafer.

Examples of a semiconductor substrate 1000 on which the n-type transistor 50 and the p-type transistor 51 are formed include an n-type or p-type silicon substrate, a germanium substrate, a silicon germanium substrate, and a compound semiconductor substrate (e.g., a GaAs substrate, an InP substrate, a GaN substrate, a SiC substrate, a GaP substrate, a GaInAsP substrate, and a ZnSe substrate). In FIG. 10, a single crystal silicon substrate having p-type conductivity is used as an example.

The n-type transistor 50 and the p-type transistor 51 are electrically isolated from other transistors by an element isolation insulating film 1001. The element isolation insulating film 1001 can be formed by a selective oxidation method (local oxidation of silicon (LOCOS) method), a trench isolation method, or the like.

Specifically, the n-type transistor 50 includes n-type impurity regions 1002 and 1003 that are formed in the semiconductor substrate 1000 and function as a source region and a drain region, a gate electrode 1004, and a gate insulating film 1005 provided between the semiconductor substrate 1000 and the gate electrode 1004. The gate electrode 1004 overlaps with a channel formation region 1006 formed between the n-type impurity regions 1002 and 1003, with the gate insulating film 1005 placed between the gate electrode 1004 and the channel formation region.

The p-type transistor 51 includes an n-well region 1031 and p-type impurity regions 1007 and 1008 functioning as a source region and a drain region, which are formed in the semiconductor substrate 1000, a gate electrode 1009, and a gate insulating film 1010 provided between the semiconductor substrate 1000 and the gate electrode 1009. The gate electrode 1009 overlaps with a channel formation region 1011 formed between the p-type impurity regions 1007 and 1008, with the gate insulating film 1010 placed between the gate electrode 1009 and the channel formation region.

An insulating film 1012 is formed over the n-type transistor 50 and the p-type transistor 51. Openings are formed in the insulating film 1012. In the openings, a conductor 1013 and a conductor 1014 are formed to be in contact the n-type impurity region 1002 and the n-type impurity region 1003, respectively, and a conductor 1015 and a conductor 1016 are formed to be in contact with the p-type impurity region 1007 and the p-type impurity region 1008, respectively.

The conductor 1013 is connected to a wiring 1017 formed over the insulating film 1012, the conductors 1014 and 1016 are connected to a wiring 1018 formed over the insulating film 1012, and the conductor 1015 is connected to a wiring 1019 formed over the insulating film 1012. An insulating film 1020, an insulating film 1021, and an insulating film 1022 are formed over the wirings 1017 to 1019.

In FIG. 10, the oxide semiconductor transistor 601 is formed over the insulating film 1022. The oxide semiconductor transistor 601 includes a gate electrode 1023 over the insulating film 1022, a gate insulating film 1024 over the gate electrode 1023, a semiconductor film 1025 that lies over the gate insulating film 1024, overlaps with the gate electrode 1023, and includes an oxide semiconductor, and a wiring 1027 and a wiring 1028 that lie over the semiconductor film 1025 and function as a source electrode and a drain electrode.

An opening is formed in the insulating films 1020 to 1022 and the gate insulating film 1024, and a conductor 1032 electrically connected to the wiring 1018 is formed in the opening. The conductor 1032 is electrically connected to the wiring 1027.

An insulating film 1026 is formed over the oxide semiconductor transistor 601. An opening is formed in the insulating film 1026, and a conductor 1029 is formed in the opening so as to be in contact with the wiring 1028. A wiring 1030 is formed over the insulating film 1026, and the conductor 1029 is electrically connected to the wiring 1030.

Note that in FIG. 10, the oxide semiconductor transistor 601 only needs to include the gate electrode 1023 on at least one side of the semiconductor film 1025. Alternatively, the oxide semiconductor transistor 601 may include a pair of gate electrodes with the semiconductor film 1025 positioned therebetween. Note that in the case where one of the gate electrodes is in the path of UV light, that gate electrode needs to be made of a material that transmits UV light.

In the case where the oxide semiconductor transistor 601 has a pair of gate electrodes with the semiconductor film 1025 positioned therebetween, one of the gate electrodes may be supplied with a signal for controlling the on/off state, and the other of the gate electrodes may be supplied with a potential from another wiring. In this case, potentials with the same level may be supplied to the pair of gate electrodes, or a fixed potential such as the ground potential may be supplied only to the other of the gate electrodes. By controlling the level of a potential supplied to the other of the gate electrodes, the threshold voltage of the transistor can be controlled.

In FIG. 10, the oxide semiconductor transistor 601 has a single-gate structure including one channel formation region corresponding to the one gate electrode 1023. However, the oxide semiconductor transistor 601 may have a multi-gate structure where a plurality of gate electrodes electrically connected to each other are provided so that a plurality of channel formation regions are included in one active layer.

A highly purified oxide semiconductor obtained by reduction of impurities such as moisture or hydrogen that serve as electron donors (donors) and reduction of oxygen vacancies is an intrinsic (i-type) semiconductor or a substantially intrinsic semiconductor. Thus, a transistor including a channel formation region in a highly purified oxide semiconductor film has an extremely low off-state current and high reliability.

In the case where an oxide semiconductor film is used as the semiconductor film, at least indium (In) or zinc (Zn) is preferably included as an oxide semiconductor. In addition, as a stabilizer for reducing variation in electrical characteristics among transistors formed using such an oxide semiconductor, gallium (Ga) is preferably contained in addition to In and Zn. Tin (Sn) is preferably contained as a stabilizer. Hafnium (Hf) is preferably contained as a stabilizer. Aluminum (Al) is preferably contained as a stabilizer. Zirconium (Zr) is preferably contained as a stabilizer.

Among oxide semiconductors, unlike silicon carbide, gallium nitride, or gallium oxide, an In—Ga—Zn-based oxide, an In—Sn—Zn-based oxide, or the like has an advantage of high mass productivity because a transistor with favorable electrical characteristics can be formed by a sputtering method or a wet process. Furthermore, unlike silicon carbide, gallium nitride, or gallium oxide, with the use of the In—Ga—Zn-based oxide, a transistor with favorable electrical characteristics can be formed over a glass substrate. Furthermore, a larger substrate can be used.

As another stabilizer, one or more lanthanoids selected from lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu) may be contained.

As the oxide semiconductor, for example, an indium oxide, a gallium oxide, a tin oxide, a zinc oxide, an In—Zn-based oxide, a Sn—Zn-based oxide, an Al—Zn-based oxide, a Zn—Mg-based oxide, a Sn—Mg-based oxide, an In—Mg-based oxide, an In—Ga-based oxide, an In—Ga—Zn-based oxide (also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide can be used.

Note that, for example, an In—Ga—Zn-based oxide means an oxide containing In, Ga, and Zn, and there is no limitation on the ratio of In:Ga:Zn. In addition, the oxide may contain a metal element other than In, Ga, and Zn. The In—Ga—Zn-based oxide has sufficiently high resistance when no electric field is applied thereto, so that off-state current can be sufficiently reduced. Furthermore, the In—Ga—Zn-based oxide has high mobility.

For example, an In—Ga—Zn-based oxide with an atomic ratio of In:Ga:Zn=1:1:1 (=⅓:⅓:⅓) or In:Ga:Zn=2:2:1 (=⅖:⅖:⅕), or an oxide with an atomic ratio close to the above atomic ratios can be used. Alternatively, an In—Sn—Zn-based oxide with an atomic ratio of In:Sn:Zn=1:1:1 (=⅓:⅓:⅓), In:Sn:Zn=2:1:3 (=⅓:⅙:½), or In:Sn:Zn=2:1:5 (=¼:⅛:⅝), or an oxide with an atomic ratio close to the above atomic ratios may be used.

For example, with the In—Sn—Zn-based oxide, a high mobility can be relatively easily obtained. However, mobility can be increased by reducing the defect density in the bulk also in the case of using the In—Ga—Zn-based oxide.

In this specification, the term “parallel” indicates that the angle formed between two straight lines is greater than or equal to −10° and less than or equal to 10°, and accordingly also includes the case where the angle is greater than or equal to −5° and less than or equal to 5. In addition, the term “substantially parallel” indicates that the angle formed between two straight lines is greater than or equal to −30° and less than or equal to 30°. In addition, the term “perpendicular” indicates that the angle formed between two straight lines is greater than or equal to 80° and less than or equal to 100°, and accordingly also includes the case where the angle is greater than or equal to 85° and less than or equal to 95°. In addition, the term “substantially perpendicular” indicates that the angle formed between two straight lines is greater than or equal to 60° and less than or equal to 120°.

In this specification, trigonal and rhombohedral crystal systems are included in a hexagonal crystal system.

A structure of the oxide semiconductor film will be described below.

An oxide semiconductor film is classified roughly into a non-single-crystal oxide semiconductor film and a single crystal oxide semiconductor film. The non-single-crystal oxide semiconductor film includes any of a c-axis aligned crystalline oxide semiconductor (CAAC-OS) film, a polycrystalline oxide semiconductor film, a microcrystalline oxide semiconductor film, an amorphous oxide semiconductor film, and the like.

First, a CAAC-OS film is described.

The CAAC-OS film is one of oxide semiconductor films having a plurality of c-axis aligned crystal parts.

In a combined analysis image (also referred to as a high-resolution TEM image) of a bright-field image and a diffraction pattern of a CAAC-OS film, which is obtained using a transmission electron microscope (TEM), a plurality of crystal parts can be observed. However, in the high-resolution TEM image, a boundary between crystal parts, that is, a grain boundary is not clearly observed. Thus, in the CAAC-OS film, a reduction in electron mobility due to the grain boundary is less likely to occur.

According to the high-resolution cross-sectional TEM image of the CAAC-OS film observed in a direction substantially parallel to a sample surface, metal atoms are arranged in a layered manner in the crystal parts. Each metal atom layer has a morphology reflecting unevenness of a surface where the CAAC-OS film is formed (hereinafter, a surface where the CAAC-OS film is formed is also referred to as a formation surface) or a top surface of the CAAC-OS film, and is arranged parallel to the formation surface or the top surface of the CAAC-OS film.

On the other hand, according to the high-resolution plan-view TEM image of the CAAC-OS film observed in a direction substantially perpendicular to the sample surface, metal atoms are arranged in a triangular or hexagonal configuration in the crystal parts. However, there is no regularity of arrangement of metal atoms between different crystal parts.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

Note that when the CAAC-OS film with an InGaZnO₄ crystal is analyzed by an out-of-plane method, a peak may also be observed when 2θ is around 36°, in addition to the peak at 2θ of around 31°. The peak at 2θ of around 36° indicates that a crystal having no c-axis alignment is included in part of the CAAC-OS film. It is preferable that in the CAAC-OS film, a peak appear when 2θ is around 31 and that a peak not appear when 2θ is around 36°.

The CAAC-OS film is an oxide semiconductor film having low impurity concentration. The impurity is an element other than the main components of the oxide semiconductor film, such as hydrogen, carbon, silicon, or a transition metal element. In particular, an element that has higher bonding strength to oxygen than a metal element included in the oxide semiconductor film, such as silicon, disturbs the atomic arrangement of the oxide semiconductor film by depriving the oxide semiconductor film of oxygen and causes a decrease in crystallinity. Further, a heavy metal such as iron or nickel, argon, carbon dioxide, or the like has a large atomic radius (molecular radius), and thus disturbs the atomic arrangement of the oxide semiconductor film and causes a decrease in crystallinity when it is contained in the oxide semiconductor film. Note that the impurity contained in the oxide semiconductor film might serve as a carrier trap or a carrier generation source.

The CAAC-OS film is an oxide semiconductor film having a low density of defect states. In some cases, oxygen vacancies in the oxide semiconductor film serve as carrier traps or serve as carrier generation sources when hydrogen is captured therein.

The state in which impurity concentration is low and density of defect states is low (the number of oxygen vacancies is small) is referred to as a “highly purified intrinsic” or “substantially highly purified intrinsic state. A highly purified intrinsic or substantially highly purified intrinsic oxide semiconductor film has few carrier generation sources, and thus can have a low carrier density. Therefore, a transistor including the oxide semiconductor film rarely has negative threshold voltage (is rarely normally on). The highly purified intrinsic or substantially highly purified intrinsic oxide semiconductor film has few carrier traps. Accordingly, the transistor including the oxide semiconductor film has little variation in electrical characteristics and high reliability. Electric charge trapped by the carrier traps in the oxide semiconductor film takes a long time to be released and might behave like fixed electric charge. Thus, the transistor including the oxide semiconductor film having high impurity concentration and a high density of defect states has unstable electrical characteristics in some cases.

With the use of the CAAC-OS film in a transistor, variation in the electrical characteristics of the transistor due to irradiation with visible light or ultraviolet light is small.

Next, a microcrystalline oxide semiconductor film will be described.

A microcrystalline oxide semiconductor film has a region in which a crystal part is observed and a region in which a crystal part is not clearly observed in a high-resolution TEM image. In most cases, the size of a crystal part included in the microcrystalline oxide semiconductor film is greater than or equal to 1 nm and less than or equal to 100 nm, or greater than or equal to 1 nm and less than or equal to 10 nm. A microcrystal with a size greater than or equal to 1 nm and less than or equal to 10 nm, or a size greater than or equal to 1 nm and less than or equal to 3 nm, is specifically referred to as nanocrystal (nc). An oxide semiconductor film including nanocrystal is referred to as an nc-OS (nanocrystalline oxide semiconductor) film. In a high-resolution TEM image of the nc-OS film, for example, a grain boundary is not clearly observed in some cases.

In the nc-OS film, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different crystal parts in the nc-OS film. Thus, the orientation of the whole film is not observed. Accordingly, in some cases, the nc-OS film cannot be distinguished from an amorphous oxide semiconductor film depending on an analysis method. For example, when the nc-OS film is subjected to structural analysis by an out-of-plane method with an XRD apparatus using an X-ray having a diameter larger than the size of a crystal part, a peak indicating a crystal plane does not appear. Further, a halo pattern is shown in a selected-area electron diffraction pattern of the nc-OS film obtained by using an electron beam having a probe diameter (e.g., 50 nm or larger) larger than the size of a crystal part. Meanwhile, spots are shown in a nanobeam electron diffraction pattern of the nc-OS film obtained by using an electron beam having a probe diameter close to or smaller than the size of a crystal part. Furthermore, in a nanobeam electron diffraction pattern of the nc-OS film, regions with high luminance in a circular (ring) pattern are shown in some cases. Moreover, in a nanobeam electron diffraction pattern of the nc-OS film, a plurality of spots are shown in a ring-like region in some cases.

The nc-OS film is an oxide semiconductor film that has high regularity as compared with an amorphous oxide semiconductor film. Therefore, the nc-OS film has a lower density of defect states than an amorphous oxide semiconductor film. Note that there is no regularity of crystal orientation between different crystal parts in the nc-OS film. Therefore, the nc-OS film has a higher density of defect states than the CAAC-OS film.

Next, an amorphous oxide semiconductor film is described.

The amorphous oxide semiconductor film has disordered atomic arrangement and no crystal part. For example, the amorphous oxide semiconductor film does not have a specific state as in quartz.

In a high-resolution TEM image of the amorphous oxide semiconductor film, crystal parts cannot be found.

When the amorphous oxide semiconductor film is subjected to structural analysis by an out-of-plane method with an XRD apparatus, a peak which shows a crystal plane does not appear. A halo pattern is observed when the amorphous oxide semiconductor film is subjected to electron diffraction. Furthermore, a spot is not observed and a halo pattern appears when the amorphous oxide semiconductor film is subjected to nanobeam electron diffraction.

Note that an oxide semiconductor film may have a structure having physical properties intermediate between the nc-OS film and the amorphous oxide semiconductor film. The oxide semiconductor film having such a structure is specifically referred to as an a-like oxide semiconductor (amorphous-like OS) film.

In a high-resolution TEM image of the a-like OS film, a void may be observed. Furthermore, in the high-resolution TEM image, there are a region where a crystal part is clearly observed and a region where a crystal part is not observed. In some cases, growth of the crystal part occurs due to the crystallization of the a-like OS film, which is induced by a slight amount of electron beam employed in the TEM observation. In contrast, in the nc-OS film that has good quality, crystallization hardly occurs by a slight amount of electron beam used for TEM observation.

Note that the crystal part size in the a-like OS film and the nc-OS film can be measured using high-resolution TEM images. For example, an InGaZnO₄ crystal has a layered structure in which two Ga—Zn—O layers are included between In—O layers. A unit cell of the InGaZnO₄ crystal has a structure in which nine layers including three In—O layers and six Ga—Zn—O layers are stacked in the c-axis direction. Accordingly, the distance between the adjacent layers is equivalent to the lattice spacing on the (009) plane (also referred to as d value). The value is calculated to be 0.29 nm from crystal structural analysis. Thus, focusing on lattice fringes in the high-resolution TEM image, each of lattice fringes in which the lattice spacing therebetween is greater than or equal to 0.28 nm and less than or equal to 0.30 nm corresponds to the a-b plane of the InGaZnO₄ crystal.

The density of an oxide semiconductor film might vary with its structure. For example, if the composition of an oxide semiconductor film is determined, the structure of the oxide semiconductor film can be estimated from a comparison between the density of the oxide semiconductor film and the density of a single crystal oxide semiconductor film having the same composition as the oxide semiconductor film. For example, the density of the a-like OS film is higher than or equal to 78.6% and lower than 92.3% of the density of the single crystal oxide semiconductor having the same composition. For example, the density of each of the nc-OS film and the CAAC-OS film is higher than or equal to 92.3% and lower than 100% of the density of the single crystal oxide semiconductor having the same composition. Note that it is difficult to deposit an oxide semiconductor film whose density is lower than 78% of the density of the single crystal oxide semiconductor film.

Specific examples of the above description are given. For example, in the case of an oxide semiconductor film with an atomic ratio of In:Ga:Zn=1:1:1, the density of single-crystal InGaZnO₄ with a rhombohedral crystal structure is 6.357 g/cm³. Thus, for example, in the case of the oxide semiconductor film with an atomic ratio of In:Ga:Zn=1:1:1, the density of an a-like OS film is higher than or equal to 5.0 g/cm³ and lower than 5.9 g/cm³. In addition, for example, in the case of the oxide semiconductor film with an atomic ratio of In:Ga:Zn=1:1:1, the density of an nc-OS film or a CAAC-OS film is higher than or equal to 5.9 g/cm³ and lower than 6.3 g/cm³.

Note that single crystals with the same composition do not exist in some cases. In such a case, by combining single crystals with different compositions at a given proportion, it is possible to calculate the density that corresponds to the density of a single crystal with a desired composition. The density of the single crystal with a desired composition may be calculated using weighted average with respect to the combination ratio of the single crystals with different compositions. Note that it is preferable to combine as few kinds of single crystals as possible for density calculation.

Note that an oxide semiconductor film may be a stacked film including two or more films of an amorphous oxide semiconductor film, a microcrystalline oxide semiconductor film, and a CAAC-OS film, for example.

For example, a CAAC-OS film is deposited by a sputtering method using a polycrystalline metal oxide target. When ions collide with the target, a crystal region included in the target might be separated from the target along the a-b plane, and a sputtered particle having a plane parallel to the a-b plane (flat-plate-like or pellet-like sputtered particle) might be separated from the target. In that case, the flat-plate-like or pellet-like sputtered particle reaches a substrate while maintaining its crystal state, so that the CAAC-OS film can be deposited.

For the deposition of the CAAC-OS film, the following conditions are preferably employed.

By reducing the amount of impurities entering the CAAC-OS film during the deposition, the crystal state can be prevented from being broken by the impurities. For example, the concentration of impurities (e.g., hydrogen, water, carbon dioxide, or nitrogen) which exist in a treatment chamber may be reduced. The concentration of impurities in a deposition gas may also be reduced. Specifically, a deposition gas whose dew point is −80° C. or lower, preferably −100° C. or lower is used.

By increasing the substrate heating temperature during the deposition, migration of a sputtered particle is likely to occur after the sputtered particle reaches a substrate surface. Specifically, the substrate heating temperature during the deposition is higher than or equal to 100° C. and lower than or equal to 740° C., preferably higher than or equal to 200° C. and lower than or equal to 500° C. By increasing the substrate heating temperature during the deposition, when the flat-plate-like or pellet-like sputtered particle reaches the substrate, migration occurs on the substrate surface, so that a flat plane of the sputtered particle is attached to the substrate.

Furthermore, preferably, the proportion of oxygen in the deposition gas is increased and the power is optimized in order to reduce plasma damage at the deposition. The proportion of oxygen in the deposition gas is 30 vol % or higher, preferably 100 vol %.

As an example of the target, an In—Ga—Zn-based oxide target is described below.

The In—Ga—Zn-based oxide target, which is polycrystalline, is made by mixing InO_{X} powder, GaO_{Y} powder, and ZnO_{Z} powder in a predetermined molar ratio, applying pressure, and performing heat treatment at a temperature higher than or equal to 1000° C. and lower than or equal to 1500° C. Note that X, Y, and Z are given positive numbers. Here, the predetermined molar ratio of InO_{X} powder to GaO_{Y} powder and ZnO_{Z} powder is, for example, 2:2:1, 8:4:3, 3:1:1, 1:1:1, 4:2:3, or 3:1:2. The kinds of powders and the molar ratio for mixing powders may be determined as appropriate depending on the desired target.

An alkali metal is not an element included in an oxide semiconductor and thus is an impurity. Likewise, an alkaline earth metal is an impurity when the alkaline earth metal is not a component of the oxide semiconductor. When an insulating film in contact with an oxide semiconductor film is an oxide, Na, among the alkali metals, diffuses into the insulating film and becomes Na⁺. Furthermore, in the oxide semiconductor film, Na cuts or enters a bond between metal and oxygen which are components of the oxide semiconductor. As a result, the electrical characteristics of the transistor deteriorate; for example, the transistor is placed in a normally-on state due to a negative shift of the threshold voltage or the mobility is decreased. In addition, the characteristics of transistors vary. Specifically, the measurement value of a Na concentration by secondary ion mass spectrometry is preferably 5×10¹⁶/cm³ or lower, further preferably 1×10¹⁶/cm³ or lower, still further preferably 1×10⁵/cm³ or lower. Similarly, the measurement value of a Li concentration is preferably 5×10⁵/cm³ or lower, further preferably 1×10¹⁵/cm³ or lower. Similarly, the measurement value of a K concentration is preferably 5×10¹⁵/cm³ or lower, further preferably 1×10¹⁵/cm³ or lower.

When metal oxide containing indium is used, silicon or carbon having higher bond energy with oxygen than indium might cut the bond between indium and oxygen, so that an oxygen vacancy may be formed. Accordingly, when silicon or carbon is contained in the oxide semiconductor film, the electrical characteristics of the transistor are likely to deteriorate as in the case of using an alkali metal or an alkaline earth metal. Thus, the concentrations of silicon and carbon in the oxide semiconductor film are preferably low. Specifically, the carbon concentration or the silicon concentration measured by secondary ion mass spectrometry is 1×10¹⁸/cm³ or lower. In this case, the deterioration of the electrical characteristics of the transistor can be prevented, so that the reliability of a semiconductor device can be improved.

A metal in the source and drain electrodes might extract oxygen from the oxide semiconductor film depending on a conductive material used for the source and drain electrodes. In such a case, oxygen vacancies are generated in a region of the oxide semiconductor film that is in contact with the source electrode or the drain electrode, and the region is changed to an n-type region.

The n-type region serves as a source region or a drain region, resulting in a decrease in the contact resistance between the oxide semiconductor film and the source electrode or the drain electrode. Accordingly, the formation of the n-type region increases the mobility and on-state current of the transistor, achieving the high-speed operation of a switch circuit using the transistor.

Note that the extraction of oxygen by a metal in the source electrode and the drain electrode is probably caused when the source electrode and the drain electrode are formed by a sputtering method or when heat treatment is performed after the formation of the source electrode and the drain electrode.

The n-type region is more likely to be formed by forming the source electrode and the drain electrode with use of a conductive material that is easily bonded to oxygen. Examples of such a conductive material include Al, Cr, Cu, Ta, Ti, Mo, and W.

The oxide semiconductor film is not limited to a single metal oxide film and may have a stacked structure of a plurality of metal oxide films. In a semiconductor film in which first to third metal oxide films are sequentially stacked, for example, the first metal oxide film and the third metal oxide film are each an oxide film that contains at least one of the metal elements contained in the second metal oxide film and whose energy at the bottom of the conduction band is closer to the vacuum level than that of the second metal oxide film by 0.05 eV or more, 0.07 eV or more, 0.1 eV or more, or 0.15 eV or more and 2 eV or less, 1 eV or less, 0.5 eV or less, or 0.4 eV or less. Furthermore, the second metal oxide film preferably contains at least indium in order to increase the carrier mobility.

In the transistor including the above semiconductor film, when a voltage is applied to the gate electrode so that an electric field is applied to the semiconductor film, a channel region is formed in the second metal oxide film whose energy at the bottom of the conduction band is the lowest. That is, since the third metal oxide film is provided between the second metal oxide film and the gate insulating film, a channel region can be formed in the second metal oxide film which is insulated from the gate insulating film.

Since the third metal oxide film contains at least one of the metal elements contained in the second metal oxide film, interface scattering is unlikely to occur at the interface between the second metal oxide film and the third metal oxide film. Thus, the movement of carriers is unlikely to be inhibited at the interface, which results in an increase in the field-effect mobility of the transistor.

If an interface level is formed at the interface between the second metal oxide film and the first metal oxide film, a channel region is formed also in the vicinity of the interface, which causes a change in the threshold voltage of the transistor. However, since the first metal oxide film contains at least one of the metal elements contained in the second metal oxide film, an interface level is unlikely to be formed at the interface between the second metal oxide film and the first metal oxide film. Accordingly, the above structure can reduce variation in the electrical characteristics of the transistor, such as the threshold voltage.

Furthermore, a plurality of oxide semiconductor films are preferably stacked so that an interface level that inhibits carrier flow is not formed at the interface between the oxide semiconductor films due to an impurity existing between the metal oxide films. This is because when an impurity exists between the stacked metal oxide films, the continuity of the lowest conduction band energy between the metal oxide films is lost, and carriers are trapped or disappear by recombination in the vicinity of the interface. By reducing an impurity existing between the metal oxide films, a continuous junction (here, particularly a U-shape well structure where energy at the bottom of the conduction band is changed continuously between the films) is formed more easily than the case of merely stacking a plurality of metal oxide films that contain at least one common metal as a main component.

In order to form such a continuous junction, the films need to be stacked successively without being exposed to the air by using a multi-chamber deposition apparatus (sputtering apparatus) provided with a load lock chamber. Each chamber of the sputtering apparatus is preferably evacuated to a high vacuum (to approximately 5×10⁻⁷ Pa to 1×10⁻⁴ Pa) by an adsorption vacuum pump such as a cryopump so that water and the like acting as impurities for the oxide semiconductor are removed as much as possible. Alternatively, a turbo molecular pump and a cold trap are preferably used in combination to prevent backflow of gas into the chamber through an evacuation system.

To obtain a highly purified intrinsic oxide semiconductor, not only high vacuum evacuation of the chambers but also high purification of a gas used in the sputtering is important. When an oxygen gas or an argon gas used as the sputtering gas has a dew point of −40° C. or lower, preferably −80° C. or lower, and more preferably −100° C. or lower and is highly purified, moisture and the like can be prevented from entering the oxide semiconductor film as much as possible.

For example, the first metal oxide film or the third metal oxide film is an oxide film containing aluminum, silicon, titanium, gallium, germanium, yttrium, zirconium, tin, lanthanum, cerium, or hafnium at a higher atomic ratio than the second metal oxide film. Specifically, the first metal oxide film or the third metal oxide film may be an oxide film containing the above element at an atomic ratio 1.5 times or more, preferably twice or more, and further preferably three times or more that in the second metal oxide film. The above element is strongly bonded to oxygen and thus has a function of suppressing generation of oxygen vacancies in the oxide film. Accordingly, the first metal oxide film or the third metal oxide film can be an oxide film in which oxygen vacancies are less likely to be generated than in the second metal oxide film.

Specifically, in the case where the second metal oxide film and the first or third metal oxide film are formed using an In-M-Zn-based oxide, if the atomic ratio of the first or third metal oxide film is In:M:Zn=x₁:y₁:z₁ and the atomic ratio of the second metal oxide film is In:M:Zn=x₂:y₂:z₂, the atomic ratios may be set so that y₁/x₁ is larger than y₂/x₂. Note that the element M is a metal element whose bonding strength to oxygen is larger than that of In, and can be, for example, Al, Ti, Ga, Y, Zr, Sn, La, Ce, Nd, or Hf. Preferably, the atomic ratios may be set so that y₁/x₁ is 1.5 or more times y₂/x₂. Further preferably, the atomic ratios may be set so that y₁/x₁ is 2 or more times y₂/x₂. Still further preferably, the atomic ratios may be set so that y₁/x₁ is 3 or more times y₂/x₂. In the second metal oxide film, y₂ is preferably larger than or equal to x₂ because the transistor can have stable electrical characteristics. Note that y₂ is preferably less than 3 times x₂ because the field-effect mobility of the transistor is lowered if y₂ is 3 or more times x₂.

The first metal oxide film and the third metal oxide film each have a thickness of 3 nm to 100 nm, preferably 3 nm to 50 nm. The second metal oxide film has a thickness of 3 nm to 200 nm, preferably 3 nm to 100 nm, and further preferably 3 nm to 50 nm.

The three oxide semiconductor films (first to third metal oxide films) can be either amorphous or crystalline. Note that the second metal oxide film in which a channel region is formed is preferably crystalline because the transistor can have stable electrical characteristics.

Note that a channel formation region means a region of a semiconductor film of a transistor that overlaps with a gate electrode and is between a source electrode and a drain electrode. Further, a channel region means a region through which current mainly flows in the channel formation region.

For example, in the case where an In—Ga—Zn-based oxide film formed by a sputtering method is used as each of the first and third metal oxide films, a target of an In—Ga—Zn-based oxide (In:Ga:Zn=1:3:2 [atomic ratio]) can be used for deposition of the first and third metal oxide films. The deposition conditions can be, for example, as follows: an argon gas (flow rate: 30 sccm) and an oxygen gas (flow rate: 15 sccm) are used as a deposition gas; pressure is 0.4 Pa; substrate temperature is 200° C.; and DC power is 0.5 kW.

In the case where the second metal oxide film is a CAAC-OS film, a target containing a polycrystalline In—Ga—Zn-based oxide (In:Ga:Zn=1:1:1 [atomic ratio]) is preferably used for the deposition. The deposition conditions can be, for example, as follows: an argon gas (flow rate: 30 sccm) and an oxygen gas (flow rate: 15 sccm) are used as a deposition gas; pressure is 0.4 Pa; substrate temperature is 300° C.; and DC power is 0.5 kW.

Although the oxide semiconductor film described above can be formed by a sputtering method, such film may be formed by another method, e.g., a thermal CVD method. A metal organic chemical vapor deposition (MOCVD) method or an atomic layer deposition (ALD) method may be employed as an example of a thermal CVD method.

A thermal CVD method has an advantage that no defect due to plasma damage is generated since it does not utilize plasma for forming a film.

Deposition by a thermal CVD method may be performed in such a manner that a source gas and an oxidizer are supplied to the chamber at a time, the pressure in a chamber is set to an atmospheric pressure or a reduced pressure, and reaction is caused in the vicinity of the substrate or over the substrate.

For example, in the case where an In—Ga—Zn—O film is formed, trimethylindium, trimethylgallium, and dimethylzinc are used. Note that the chemical formula of trimethylindium is In(CH₃)₃. The chemical formula of trimethylgallium is Ga(CH₃)₃. The chemical formula of dimethylzinc is Zn(CH₃)₂. Without limitation to the above combination, triethylgallium (chemical formula: Ga(C₂H₅)₃) can be used instead of trimethylgallium and diethylzinc (chemical formula: Zn(C₂H₅)₂) can be used instead of dimethylzinc.

For example, in the case where an oxide semiconductor film, e.g., an In—Ga—Zn—O film is formed using a deposition apparatus employing ALD, an In(CH₃)₃ gas and an O₃ gas are sequentially introduced plural times to form an In—O layer, a Ga(CH₃)₃ gas and an O₃ gas are sequentially introduced plural times to form a Ga—O layer, and then a Zn(CH₃)₂ gas and an O₃ gas are sequentially introduced plural times to form a Zn—O layer. Note that the order of these layers is not limited to this example. A mixed compound layer such as an In—Ga—O layer, an In—Zn—O layer, or a Ga—Zn—O layer may be formed by mixing of these gases. Note that although an H₂O gas which is obtained by bubbling with an inert gas such as Ar may be used instead of an O₃ gas, it is preferable to use an O₃ gas, which does not contain H. Further, instead of an In(CH₃)₃ gas, an In(C₂H₅)₃ gas may be used. Instead of a Ga(CH₃)₃ gas, a Ga(C₂H₅)₃ gas may be used. Furthermore, a Zn(CH₃)₂ gas may be used.

Note that the end portions of the semiconductor film in the transistor may be tapered or rounded.

Also in the case where a semiconductor film including stacked metal oxide films is used in the transistor, a region in contact with the source electrode or the drain electrode may be an n-type region. Such a structure increases the mobility and on-state current of the transistor and achieves high-speed operation of a semiconductor device using the transistor. Furthermore, when the semiconductor film including the stacked metal oxide films is used in the transistor, the n-type region particularly preferably reaches the second metal oxide film part of which is to be a channel region, because the mobility and on-state current of the transistor are further increased and higher-speed operation of the semiconductor device is achieved.

### Embodiment 6

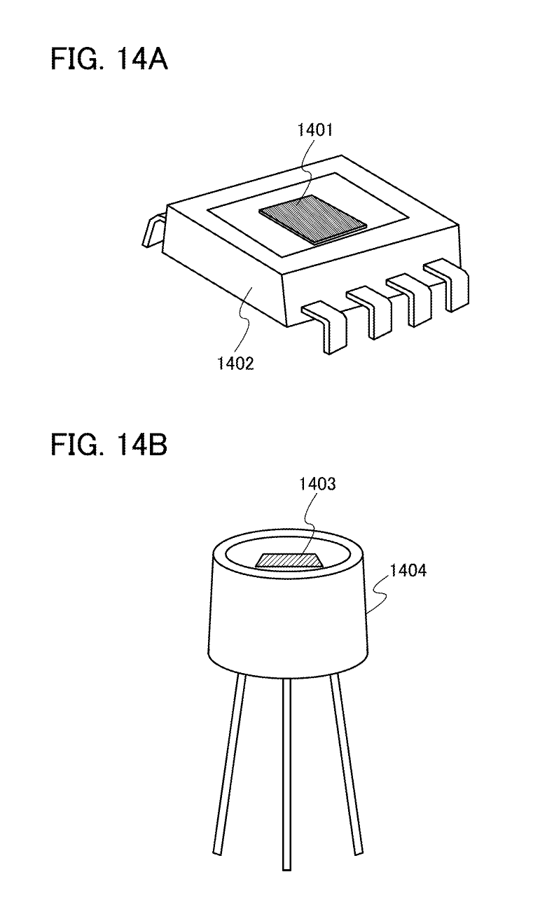

FIGS. 14A and 14B are external views of sensor ICs each including a UV sensor chip of one embodiment of the present invention. A transparent sealing member that transmits UV light needs to be provided on the chip so that the sensor IC detects UV light.

FIG. 14A illustrates an example in which a UV sensor 1401 is mounted on a dual inline package (DIP) 1402. FIG. 14B illustrates an example in which a UV sensor 1403 is mounted on a metal round package 1404. The mounting method of the UV sensor is not limited to these, and the UV sensor may be directly mounted a printed wiring board, for example.

This embodiment can be implemented in appropriate combination with any of the other embodiments.

### Embodiment 7

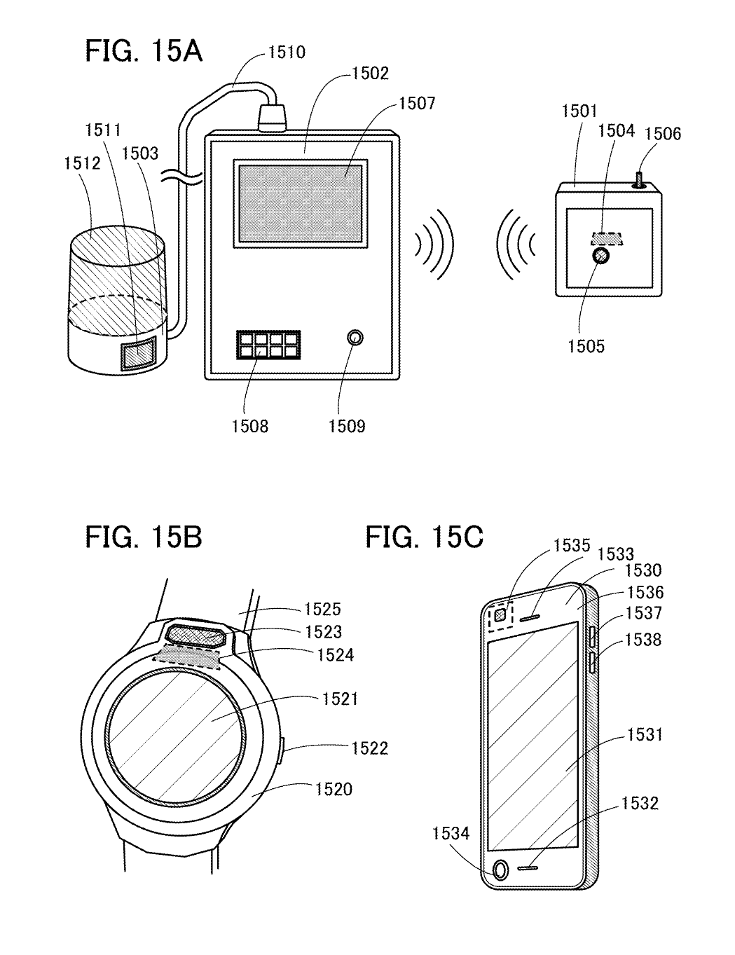

The semiconductor device of one embodiment of the present invention can be used for display devices, personal computers, or image reproducing devices provided with recording media (typically, devices which reproduce the content of recording media such as digital versatile discs (DVDs) and have displays for displaying the reproduced images). Other examples of electronic devices that can be equipped with the semiconductor device of one embodiment of the present invention are mobile phones, game machines including portable game consoles, portable data terminals, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), and vending machines. FIGS. 15A to 15C illustrate specific examples of these electronic devices.

The UV sensor, which can detect UV light emitted from a flame, is used for a fire alarm system, a boiler combustion control system, or the like. FIG. 15A illustrates a fire alarm system that includes a detector 1501, a fire alarm control panel 1502, and a notification appliance 1503.

The detector 1501 includes a UV sensor 1504 of one embodiment of the present invention, a window 1505, an operation key 1506, and the like. The UV sensor 1504 is irradiated with light passing through the window 1505. The UV sensor 1504 detects ultraviolet light emitted from a heat source such as a flame. When the UV sensor 1504 detects UV light having a radiant intensity exceeding a predetermined value, the detector 1501 transmits the information to the fire alarm control panel 1502. The fire alarm control panel 1502 includes a display portion 1507, operation keys 1508, an operation key 1509, a wiring 1510, and the like. The fire alarm control panel 1502 controls the operation of the notification appliance 1503 in accordance with information transmitted from the detector 1501. The notification appliance 1503 includes a speaker 1511, a lighting device 1512, and the like. The notification appliance 1503 has a function of raising an alarm in accordance with a command from the fire alarm control panel 1502. In FIG. 15A, the notification appliance 1503 raises an alarm using warning sound from the speaker 1511 and warning light (e.g., red light) from the lighting device 1512; alternatively, the notification appliance 1503 may give an alarm using any one of sound and light or another means.

The fire alarm control panel 1502 may command fire preventive equipment such as a shutter to perform a predetermined operation when an alarm is given. Although FIG. 15A illustrates an example where signals are wirelessly transmitted and received between the fire alarm control panel 1502 and the detector 1501, signals may be transmitted and received via a wiring or the like. In addition, although FIG. 15A illustrates an example where a signal is transmitted from the fire alarm control panel 1502 to the notification appliance 1503 via the wiring 1510, a signal may be wirelessly transmitted.

The UV sensor is expected to be used for various portable devices to reduce the effects of UV light from the Sun on the human body. FIG. 15B illustrates a wristwatch including a UV sensor of one embodiment of the present invention, which includes a housing 1520, a display portion 1521, an operation button 1522, a window 1523, a UV sensor 1524, a bracelet 1525, and the like. The UV sensor 1524 is irradiated with light passing through the window 1523.

The UV sensor 1524 detects UV light, and display based on the intensity of the UV light can be performed on the display portion 1521. In addition, an alarm can be activated to warn the user against UV exposure.

FIG. 15C illustrates a smartphone including a UV sensor of one embodiment of the present invention, which includes a housing 1530, a display portion 1531, a microphone 1532, a speaker 1533, a camera 1534, a window 1535, a UV sensor 1536, an operation button 1537, and an operation 1538. The UV sensor 1536 is irradiated with light passing through the window 1535.

The UV sensor 1536 detects UV light, and display based on the intensity of the UV light can be performed on the display portion 1531. In addition, an audio alarm can be heard from the speaker 1533 to warn the user against UV exposure.

This embodiment can be implemented in appropriate combination with any of the other embodiments.

As described above, an electronic component including the UV sensor described in the above embodiments is provided in each of the electronic devices described in this embodiment. It is thus possible to achieve the electronic devices each including a UV sensor with low costs and favorable temperature characteristics.

This application is based on Japanese Patent Application serial No. 2014-104819 filed with Japan Patent Office on May 21, 2014, the entire contents of which are hereby incorporated by reference.

What is claimed is:

1. A sensor for measuring an intensity of UV light, comprising:
a transistor comprising:
an oxide semiconductor layer including a channel formation region; and
a drain electrode having a comb shape,
wherein the sensor is configured to measure an intensity of UV light by measuring a current that is generated when the transistor is irradiated with UV light.

2. The sensor according to claim 1, wherein the current is an off-state current of the transistor.

3. The sensor according to claim 1, wherein the transistor has a bottom-gate structure.

4. The sensor according to claim 1, wherein a contour of a tooth of the comb of the drain electrode includes projections and depressions in a plan view.

5. The sensor according to claim 1, wherein the oxide semiconductor layer includes In, Ga, and Zn.

6. An electronic device comprising the sensor according to claim 1.

7. A sensor for measuring an intensity of UV light, comprising:
a transistor comprising:
an oxide semiconductor layer including a channel formation region; and
a source electrode and a drain electrode over the oxide semiconductor layer,
wherein the sensor is configured to measure an intensity of UV light by measuring a current that is generated when the transistor is irradiated with UV light, and
wherein a total length of sides of the drain electrode which overlap with the oxide semiconductor layer is longer than a total length of sides of the source electrode which overlap with the oxide semiconductor layer.

8. The sensor according to claim 7, wherein the current is an off-state current of the transistor.

9. The sensor according to claim 7, wherein the transistor has a bottom-gate structure.

10. The sensor according to claim 7,
wherein the source electrode and the drain electrode face each other, and
wherein the drain electrode has a comb shape.

11. The sensor according to claim 10, wherein a contour of a tooth of the comb of the drain electrode includes projections and depressions in a plan view.

12. The sensor according to claim 7,
wherein the drain electrode is provided to surround the source electrode, and
wherein an inner circumference of the drain electrode, which corresponds to the border between the drain electrode and the channel formation region, has a comb shape.

13. The sensor according to claim 7, wherein the oxide semiconductor layer includes In, Ga, and Zn.

14. An electronic device comprising the sensor according to claim 7.

15. A sensor for measuring an intensity of UV light, comprising:
a transistor comprising:
a gate electrode:
an oxide semiconductor layer including a channel formation region over the gate electrode; and
a source electrode and a drain electrode facing each other over the oxide semiconductor layer, the drain electrode having a comb shape,
wherein the sensor is configured to measure an intensity of UV light by measuring a current that is generated when the transistor is irradiated with UV light, and
wherein a total length of sides of the drain electrode which overlap with the oxide semiconductor layer is longer than a total length of sides of the source electrode which overlap with the oxide semiconductor layer.

16. The sensor according to claim 15, wherein the current is an off-state current of the transistor.

17. The sensor according to claim 15, wherein a contour of a tooth of the comb of the drain electrode includes projections and depressions in a plan view.

18. The sensor according to claim 15, wherein the oxide semiconductor layer includes In, Ga, and Zn.

19. An electronic device comprising the sensor according to claim 15.
